(19) United States
(12) Patent Application Publication
(10) Pub. No.: US 2025/0069953 A1
(43) Pub. Date: Feb. 27, 2025

(54) BREAKING METHOD

(71) Applicant: DISCO CORPORATION, Tokyo (JP)

(72) Inventors: Shinya ARUGA, Tokyo (JP); Norihisa ARIFUKU, Tokyo (JP)

(21) Appl. No.: 18/809,484

(22) Filed: Aug. 20, 2024

(30) Foreign Application Priority Data
Aug. 25, 2023 (JP) 2023-137185

(51) Int. Cl. H01L 21/78

(52) U.S. Cl. CPC H01L 21/78

(57) ABSTRACT

A breaking method for dividing, along a division line, a wafer having division starting points formed along the division line. The breaking method includes a protective sheet arrangement step of arranging, on a side of a front surface of the wafer, a protective sheet that has a front surface and back surface formed flat and is free of any glue layer, an alignment step of, after performing the protective sheet arrangement step, capturing an image of the front surface of the wafer from a side of the protective sheet and conducting position matching between the division line and a pressing member, and a dividing step of, after performing the alignment step, dividing the wafer along the division line by pressing the pressing member against the wafer along the division line.

### BACKGROUND OF THE INVENTION

### Field of the Invention

The present invention relates to a breaking method.

### Description of the Related Art

As a method for fabricating chips by dividing a semiconductor wafer, a method is known in which a laser beam of a wavelength having transmissivity for the wafer is moved along each division line with a focal point of the laser beam positioned inside the wafer to form modified layers as division starting points, and an external force is applied to the modified layers to divide the wafer (see, for example, Japanese Patent No. 3408805).

The division of the wafer is performed by arranging a self-adhesive sheet and a protective sheet on a back surface and front surface of the wafer, respectively, and pressing a dividing press blade against the wafer from the side of the protective sheet along the division lines.

### SUMMARY OF THE INVENTION

However, a sheet that is used as the protective sheet is low in transparency, so that it is difficult to conduct position matching between the dividing press blade and the division lines. There is accordingly a risk that, due to positioning of the press blade at a wrong place, a division failure may be induced or the wafer may be damaged.

The present invention therefore has as an object thereof the provision of a breaking method which decreases such a division failure and also the risk of damage to a wafer.

In accordance with an aspect of the present invention, there is provided a breaking method for dividing, along a division line, a wafer having division starting points formed along the division line. The breaking method includes a protective sheet arrangement step of arranging, on a side of a front surface of the wafer, a protective sheet that has a front surface and back surface formed flat and is free of any glue layer, an alignment step of, after performing the protective sheet arrangement step, capturing an image of the front surface of the wafer from a side of the protective sheet and conducting position matching between the division line and a pressing member, and a dividing step of, after performing the alignment step, dividing the wafer along the division line by pressing the pressing member against the wafer along the division line.

Preferably, in the dividing step, the wafer may be held from above and below thereof by a pair of holding members in a region adjacent to the division line, and at the same time, the wafer may be pressed from the side of the protective sheet by the pressing member in another region adjacent to the division line on an opposite side to the paired holding members with the division line interposed between the other region and the paired holding members, whereby the wafer is divided along the division line. Preferably, the protective sheet may contain an antistatic agent.

The present invention exhibits advantages that a division failure can be decreased and the risk of damage to a wafer can also be decreased.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically depicting a wafer to be divided by a breaking method according to an embodiment of the present invention.

FIG. 2 is a cross-sectional view schematically depicting the wafer depicted in FIG. 1;

FIG. 3 is a flow chart illustrating a flow of the breaking method according to the embodiment;

FIG. 4 is a cross-sectional view schematically depicting a protective sheet arrangement step of the breaking method depicted in FIG. 3;

FIG. 5 is a perspective view schematically depicting a configuration example of a breaking machine that performs an alignment step and dividing step of the breaking method depicted in FIG. 3;

FIG. 6 is a perspective view schematically depicting the configuration of a lower holding unit of a holding unit in the breaking machine depicted in FIG. 5;

FIG. 7 is a side view schematically depicting, partly in cross-section, the configuration of an upper holding unit of the holding unit in the breaking machine depicted in FIG. 5;

FIG. 8 is a side view schematically depicting, partly in cross-section, a pressing member in the breaking machine depicted in FIG. 5;

FIG. 9 is a front view schematically depicting, partly in cross-section, a load measuring unit as seen in a direction of an arrow IX indicated in FIG. 8;

FIG. 10 is a side view schematically depicting, partly in cross-section, the alignment step of the breaking method depicted in FIG. 3;

FIG. 11 is a side view schematically depicting, partly in cross-section, the dividing step of the breaking method depicted in FIG. 3, in which devices adjacent to a division line, along which the wafer depicted in FIG. 1 is to be divided, are held between holding members;

FIG. 12 is a side view schematically depicting, partly in cross-section, the dividing step of the breaking method depicted in FIG. 3, in which the wafer depicted in FIG. 1 has been divided along the division line;

FIG. 13 is a side view schematically depicting, on an enlarged scale and partly in cross-section, a part XIII in FIG. 12;

FIG. 14 is a view presenting an image of the wafer as acquired in the alignment step of the breaking method according to the embodiment;

FIG. 15 is a view presenting an image of a wafer, which is of the same kind as the wafer depicted in FIG. 1, as acquired by capturing an image using a protective sheet as a comparative example;

FIG. 16 is a perspective view schematically depicting another wafer as a modification of the wafer depicted in FIG. 1;

FIG. 17 is a cross-sectional view schematically depicting the wafer depicted in FIG. 16;

FIG. 18 is a side view schematically depicting, partly in cross-section, a modification of the alignment step depicted in FIG. 10;

FIG. 19 is a side view schematically depicting, partly in cross-section, a modification of the dividing step depicted in FIG. 11; and

FIG. 20 is a side view schematically depicting, partly in cross-section, a modification of the dividing step depicted in FIG. 12.

### DETAILED DESCRIPTION OF THE PREFERRED EMBODIMENT

With reference to the attached drawings, a description will be made in detail about an embodiment of the present invention. However, the present invention shall not be limited by details that will be described in the subsequent embodiment. The elements of configurations that will hereinafter be described include those readily conceivable to persons skilled in the art and substantially the same ones. Further, the configurations that will hereinafter be described can be combined appropriately. Furthermore, various omissions, replacements, and modifications of configurations can be made without departing from the spirit of the present invention.

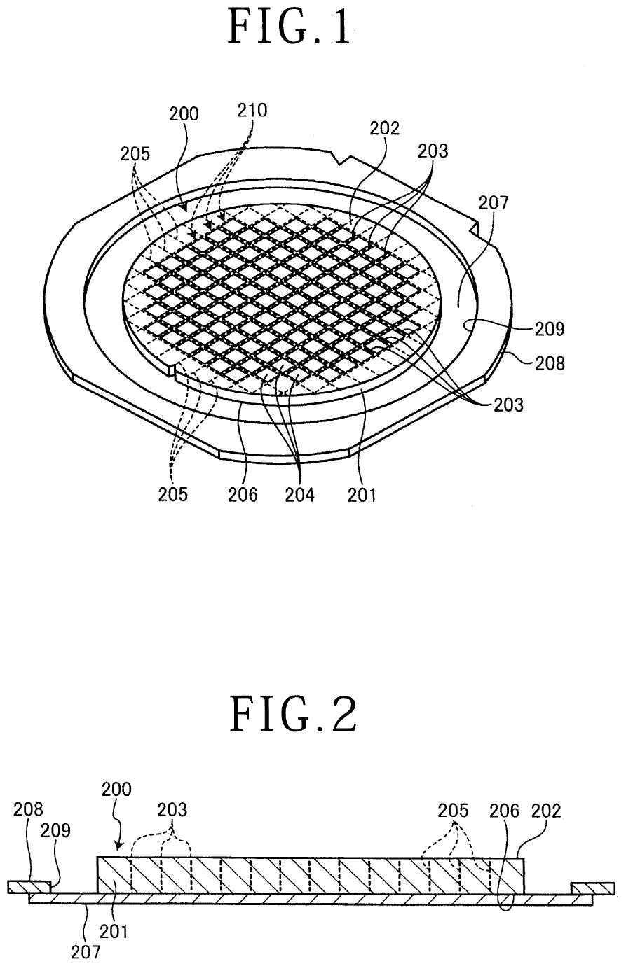

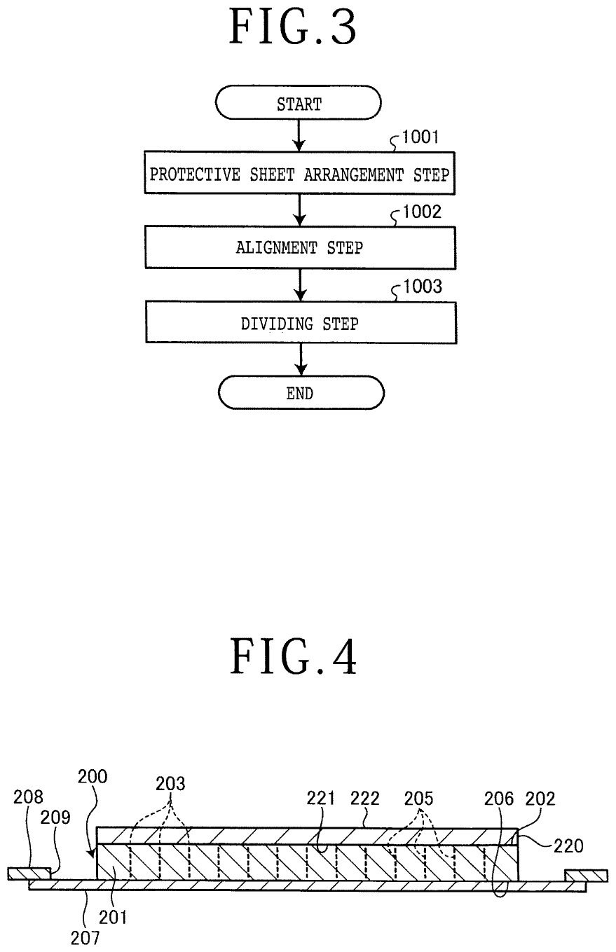

A breaking method according to the embodiment of the present invention will be described on the basis of the drawings. FIG. 1 is a perspective view schematically depicting a wafer to be divided by the breaking method according to this embodiment. FIG. 2 is a cross-sectional view schematically depicting the wafer depicted in FIG. 1. FIG. 3 is a flow chart illustrating a flow of the breaking method according to this embodiment. The breaking method according to this embodiment serves to divide a wafer 200, which is depicted in FIG. 1, into individual chips 210.

The wafer 200 to be divided by the breaking method according to this embodiment is, for example, a disk-shaped semiconductor wafer, an optical device wafer, or the like, which uses glass, sapphire, SiC, or the like as a substrate 201. As depicted in FIG. 1, the wafer 200 includes a plurality of intersecting division lines 203 set on a front surface 202, and devices 204 formed in regions defined by the division lines 203. It is to be noted that, in the present invention, the substrate 201 may be made from a material other than glass, sapphire, SiC, or the like, and no devices 204 may be formed on the wafer 200.

The devices 204 are, for example, integrated circuits such as general integrated circuits (ICs) or large-scale integration (LSI) circuits, image sensors such as charge coupled devices (CCDs), or complementary metal oxide semiconductors (CMOSs), optical devices such as light-emitting diodes (LEDs), or memories (semiconductor storage devices).

As depicted in FIGS. 1 and 2, the wafer 200 also includes division starting points 205 along the division lines 203. In this embodiment, the division starting points 205 are modified layers formed along the division lines 203 inside the substrate 201. Here, the term “modified layers” means regions in each of which one or more of the density, refractive index, mechanical strength, and other physical properties have changed to a level or levels different from the corresponding one or ones of surrounding regions, and fusion treated regions, cracked regions, dielectric breakdown regions, refractive index change regions, regions where these regions are present in a mixed manner, and the like can be exemplified. The modified layers are lower in mechanical strength than other locations in the substrate 201.

As also depicted in FIGS. 1 and 2, a disk-shaped tape 207 of a larger diameter than that of the wafer 200 is bonded at a central part thereof to a back surface 206 of the wafer 200, the back surface 206 being on an opposite side to the front surface 202, and a ring-shaped annular frame 208, which has an inner diameter greater than an outer diameter of the wafer 200, is bonded to an outer edge portion of the tape 207.

The tape 207 includes a base material layer formed with a resin having non-self-adhesiveness and flexibility, and a glue layer stacked on the base material layer and formed with a resin having self-adhesiveness and flexibility, the glue layer being bonded to the wafer 200 and the annular frame 208. The tape 207 also has stretchability. In this embodiment, the wafer 200 is therefore placed inside an opening 209 of the annular frame 208 bonded to the back surface 206, via the tape 207.

The breaking method according to this embodiment divides the wafer 200, in which the division starting points 205 are formed along the division lines 203, into the individual chips 210 by dividing the wafer 200 along the division lines 203. It is to be noted that each chip 210 incudes a portion of the substrate 201 and the device 204 formed on a surface of the substrate 201. As illustrated in FIG. 3, the breaking method includes a protective sheet arrangement step 1001, an alignment step 1002, and a dividing step 1003.

FIG. 4 is a cross-sectional view schematically depicting the protective sheet arrangement step 1001 of the breaking method depicted in FIG. 3. The protective sheet arrangement step 1001 arranges, on the side of the front surface 202 of the wafer 200, a protective sheet 220 that is formed flat at a front surface 221 and back surface 222 thereof and is free of any glue layer.

In the protective sheet arrangement step 1001, the protective sheet 220 of the same diameter as the wafer 200 is placed on the front surface 202 of the wafer 200 as depicted in FIG. 4. It is to be noted that, in the present invention, the protective sheet 220 or the like is not heated, and the protective sheet 220 or the like is not bonded to the front surface 202 of the wafer 200 by pressing it against the front surface 202 of the wafer 200 while it is heated, in the protective sheet arrangement step 1001. It is also to be noted that, although the protective sheet 220 has a disk shape of the same diameter as the wafer 200 in this embodiment, the protective sheet 220 is not limited to such a protective sheet and may be formed in a disk shape of a larger diameter than that of the wafer 200.

In this embodiment, the protective sheet 220 is what is called a glue-free tape formed with only a base material layer of a non-self-adhesive thermoplastic resin such as polyolefin, typically polyethylene. In general, what is called a glue-free tape that is to be bonded to the wafer 200 and is formed with only a base material layer of a thermoplastic resin is provided at surfaces thereof with roughness intentionally formed to improve its handling properties, and has a surface roughness (Ra) of 1.2 μm at its surfaces. In this embodiment, however, the protective sheet 220 is formed flat at the front surface 221 and the back surface 222, and the surface roughness (Ra) on the front surface 221 and the back surface 222 is 0.01 μm or greater and 0.5 μm or smaller, with 0.1 μm being desired.

In this embodiment, one produced using a general method such as casting is used as the protective sheet 220. The protective sheet 220 may be also produced by forming the surface profiles of rolls, which are to be used in stretching, like a mirror surface beforehand and transferring the mirror surfaces of the rolls to the front surface 221 and the back surface 222. As an alternative, the protective sheet 220 may also be made flat at the front surface 221 and the back surface 222 by processing means, such as air knives, for additionally making their surface profiles flat instead of the rolls.

In this embodiment, the protective sheet 220 desirably has a thickness of 50 μm or greater and 150 μm or smaller, preferably 80 μm or greater and 100 μm or smaller, because the protective sheet 220 is poor in handling properties and sticks to itself if its thickness is unduly small, for example, smaller than 50 μm, and forces are hardly allowed to transmit upon breaking if its thickness is excessively large, for example, larger than 150 μm.

In this embodiment, the protective sheet 220 also has a storage modulus of 10 MPa or greater and 1 GPa or smaller at 10° C. or higher and 30° C. or lower. In the present invention, the protective sheet 220 may undergo peeling electrification when peeled from the wafer 200. To suppress damage to the wafer 200 upon peeling the protective sheet 220, an antistatic agent (for example, at least one of polyethylene glycol methacrylate copolymers, polyether ester amides, or polyether esters) may be contained. In the present invention, an antistatic spray may also be applied to the protective sheet 220 instead of (or in addition to) the antistatic agent to form antistatic films on the front surface 221 and the back surface 222, respectively.

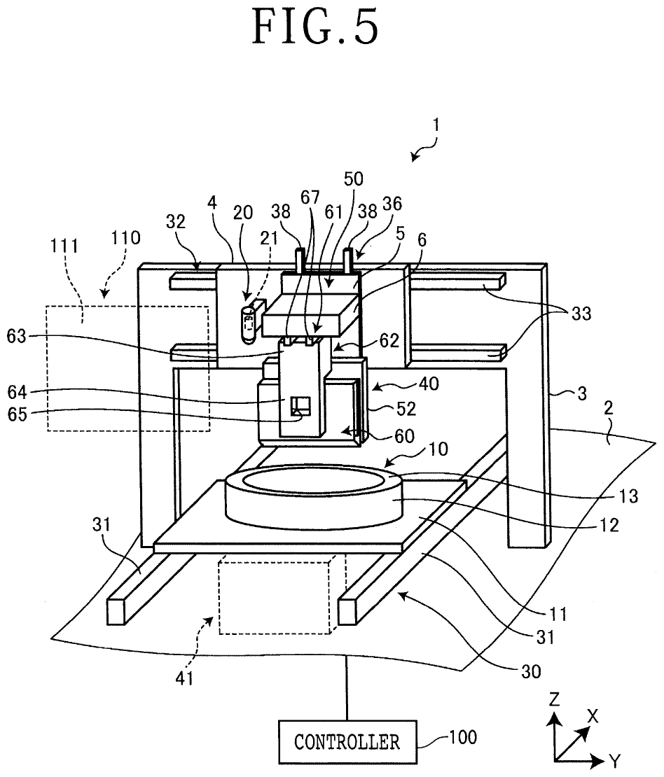

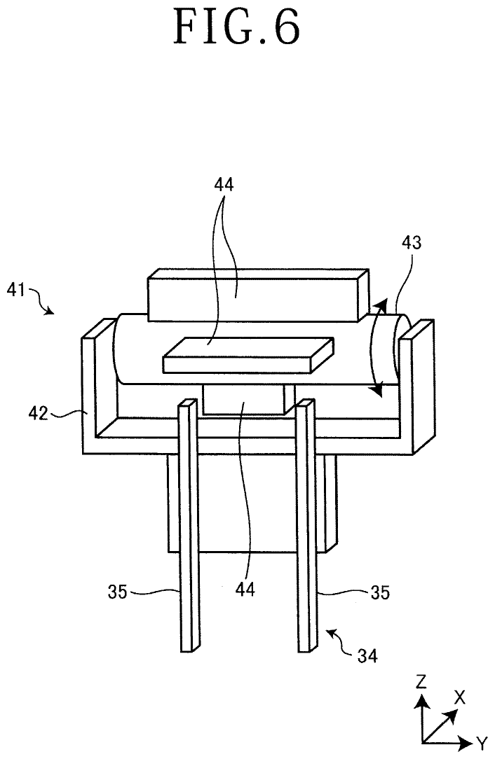

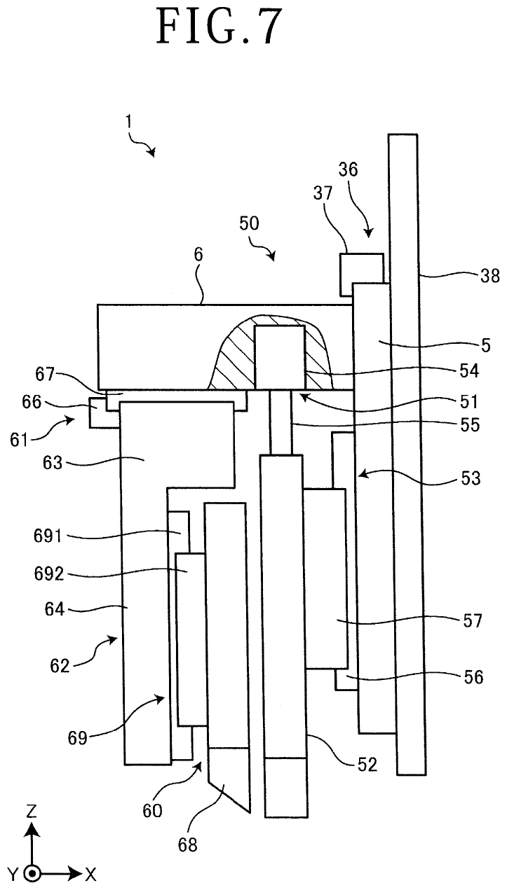

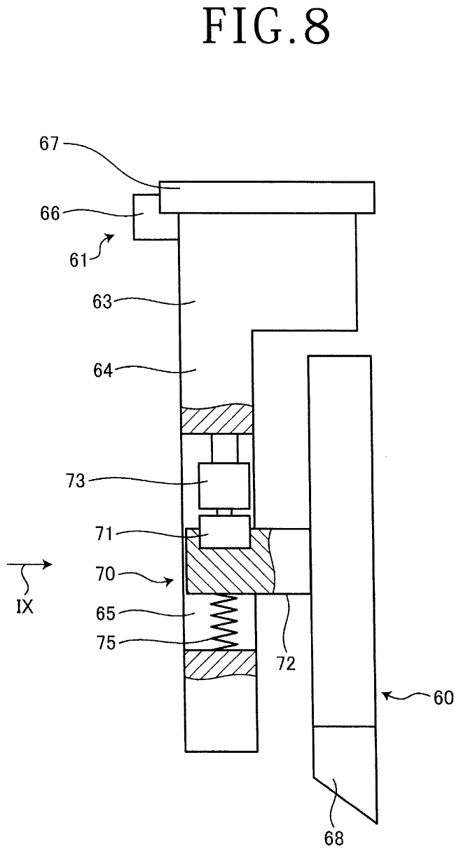

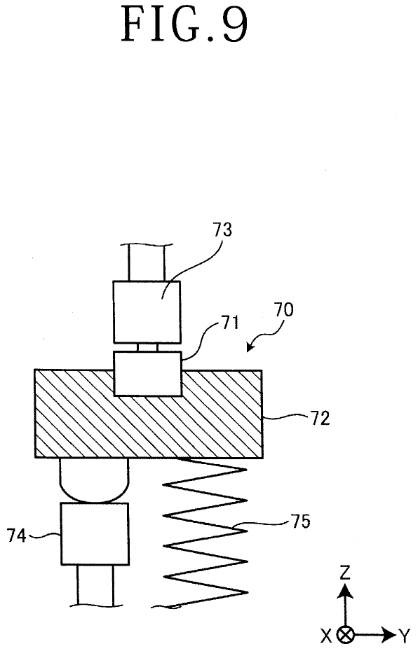

Next, a description will be made of a breaking machine 1 depicted in FIG. 5, which performs the alignment step and the dividing step. FIG. 5 is a perspective view schematically depicting, by way of example, the configuration of the breaking machine 1 that performs the alignment step 1002 and dividing step 1003 of the breaking method depicted in FIG. 3. FIG. 6 is a perspective view schematically depicting the configuration of a lower holding unit of a holding unit in the breaking machine 1 depicted in FIG. 5. FIG. 7 is a side view schematically depicting, partly in cross-section, the configuration of an upper holding unit of the holding unit in the breaking machine 1 depicted in FIG. 5. FIG. 8 is a side view schematically depicting, partly in cross-section, a pressing member in the breaking machine 1 depicted in FIG. 5. FIG. 9 is a front view schematically depicting, partly in cross-section, a load measuring unit as seen in a direction of an arrow IX indicated in FIG. 8.

The breaking machine 1 depicted in FIG. 5 divides the wafer 200 into the individual chips 210 by dividing the wafer 200 using the division starting points 205 as starting points. As depicted in FIG. 5, the breaking machine 1 includes a frame fixing unit 10, a detection unit 20, a holding unit 40, a pressing member 60, a controller 100, a display unit 110, and an undepicted input unit.

The frame fixing unit 10 serves to fix the annular frame 208. The frame fixing unit 10 includes a moving frame 11, and a frame fixing member 12. The moving frame 11 is arranged on a machine main body 2 movably in an X-axis direction, which is parallel to a horizontal direction, by an X-axis moving unit 30. The frame fixing member 12 is arranged on the moving frame 11.

The frame fixing member 12 is formed in an annular shape having inner and outer diameters equivalent to the inner and outer diameters of the annular frame 208, and has an upper surface serving as a holding surface 13 on which the annular frame 208 is to be placed via the outer peripheral portion of the tape 207. The holding surface 13 is flat along the horizontal direction. In this embodiment, the frame fixing member 12 has suction apertures opening in the holding surface 13 and connected to an undepicted suction source.

Air is drawn by the suction source through the suction apertures, whereby the frame fixing unit 10 draws and fixes, via the tape 207, the annular frame 208 placed on the holding surface 13. In the present invention, if the annular frame 208 is formed with a magnetic material, the frame fixing unit 10 may include a magnet (permanent magnet or electromagnet) arranged in the frame fixing member 12, and by a magnetic force, may attract and fix the annular frame 208 placed on the holding surface 13. If the annular frame 208 is formed with a nonmagnetic material, on the other hand, the frame fixing unit 10 may include clamp mechanisms that hold the annular frame 208 between themselves and the holding surface 13 to fix the annular frame 208. Further, the frame fixing unit 10 is rotatable by an undepicted rotary drive mechanism about an axis of rotation parallel to a Z-axis direction (also called a “vertical direction”).

The X-axis moving unit 30 includes a known ball screw, a known motor, and known guide rails 31. The ball screw is arranged on the machine main body 2, and is disposed rotatably about an axis of rotation. The motor rotates the ball screw about the axis of rotation such that the moving frame 11 and the frame fixing member 12 are moved in the X-axis direction. The guide rails 31 support the moving frame 11 movably in the X-axis direction.

The detection unit 20 serves to detect the division lines 203 on the wafer 200 with the annular frame 208 fixed by the frame fixing unit 10. The detection unit 20 is arranged on a moving table 4 movable by a Y-axis moving unit 32 in a Y-axis direction, which is parallel to the horizontal direction and is orthogonal to the X-axis direction, on a gantry frame 3 disposed upright from the machine main body 2 and astride the guide rails 31 of the X-axis moving unit 30.

The detection unit 20 includes an image capture camera 21 provided with an image sensor, such as a CCD image sensor or a CMOS image sensor, that captures an image of an object to which an objective lens opposes in the Z-axis direction parallel to the vertical direction. The detection unit 20 acquires an image captured by the image sensor, and outputs the acquired image to the controller 100. Described specifically, the detection unit 20 captures an image of the wafer 200 placed in the opening 209 of the annular frame 208 fixed by the frame fixing unit 10, and acquires an image for conducting an alignment to conduct position matching between a desired one of the division lines 203 of the wafer 200 and the pressing member 60 or the like.

The gantry frame 3 and the moving table 4 are in the shape of flat plates, both surfaces of each of which are parallel to the Z-axis direction that is parallel to the vertical direction, and are disposed parallel to each other with an interval in the X-axis direction therebetween. The Y-axis moving unit 32 includes a known ball screw, a known motor, and known guide rails 33. The ball screw is disposed on the gantry frame 3, and is arranged rotatably about an axis of rotation. The motor rotates the ball screw about the axis of rotation such that the moving table 4 is moved in the Y-axis direction. The guide rails 33 support the moving table 4 movably in the Y-axis direction.

The holding unit 40 serves to hold the devices 204 in a region adjacent in a +X direction to the division line 203, along which the wafer 200 is to be divided, from above and below along the Z-axis direction. As depicted in FIG. 5, the holding unit 40 includes a lower holding unit 41, and an upper holding unit 50.

The lower holding unit 41 is arranged below the frame fixing unit 10, and serves to press, from below, the devices 204 in the region adjacent in the +X direction to the division line 203, along which the wafer 200 placed in the opening 209 of the annular frame 208 fixed by the frame fixing unit 10 is to be divided. As depicted in FIG. 6, the lower holding unit 41 includes a bracket 42 disposed movably up and down in the Z-axis direction by a Z-axis moving unit 34, a rotor 43 supported rotatably about an axis of rotation on the bracket 42, and a plurality of rectangular holding members 44 protruding from an outer peripheral surface of the rotor 43 and having different lengths from one another in the Y-axis direction.

The rotor 43 is arranged with its axis of rotation extending parallel to the Y-axis direction, and is rotatably supported at opposite ends thereof by the bracket 42. The rotor 43 is rotated about its axis of rotation by an undepicted rotating mechanism. The rectangular holding members 44 are formed in the shape of rectangular plates, which are constant in thickness and are linear in the Y-axis direction, and are also formed with different lengths to have varied lengths in the Y-axis direction. The longest one of the rectangular holding members 44 has a length equivalent to that of the longest division line 203 of the wafer 200, while the shortest rectangular holding member 44 has a length equivalent to that of the shortest division line 203 of the wafer 200.

The rectangular holding members 44 are each changed in the protruding direction by rotation of the rotor 43. Now, a focus is placed on the rectangular holding member 44, which is directed upward along the Z-axis direction from the rotor 43, among the rectangular holding members 44. When the rotor 43 is moved down by the Z-axis moving unit 34 via the bracket 42, the upwardly directed rectangular holding member 44 is located at its upper end below the tape 207 bonded to the wafer 200 that is placed in the opening 209 of the annular frame 208 fixed by the frame fixing unit 10. When the rotor 43 is moved up by the Z-axis moving unit 34 via the bracket 42, on the other hand, the upwardly directed rectangular holding member 44 is located at its upper end above the wafer 200 that is placed in the opening 209 of the annular frame 208 fixed by the frame fixing unit 10. When the rotor 43 is moved up by the Z-axis moving unit 34 via the bracket 42, the upwardly directed rectangular holding member 44 therefore presses at its upper end the devices 204 in the region adjacent in the +X direction to the division line 203, along which the wafer 200 is to be divided, upward from the side of the back surface 206.

In other words, the lower holding unit 41 can select, as an upwardly directed rectangular holding member, one of the rectangular holding members 44, the one rectangular holding member 44 having a desired length in the Y-axis direction, specifically a length equal or close to the length of the division line 203 along which the wafer 200 is to be divided, by changing the direction of the rotor 43 about its axis of rotation. With the rectangular holding member 44 so selected, the lower holding unit 41 presses the devices 204 in the region adjacent in the +X direction to the division line 203, along which the wafer 200 is to be divided, upward from the side of the back surface 206.

The Z-axis moving unit 34 includes a known ball screw, a known motor, and known guide rails 35. The ball screw is disposed rotatably about an axis of rotation. The motor rotates the ball screw about the axis of rotation such that the bracket 42 is moved up or down in the Z-axis direction. The guide rails 35 support the bracket 42 movably up and down in the Z-axis direction.

The upper holding unit 50 is arranged above the frame fixing unit 10, and serves to hold, between itself and the lower holding unit 41, the devices 204 pressed from below by the lower holding unit 41 in the region adjacent in the +X direction to the division line 203, along which the wafer 200 placed in the opening 209 of the annular frame 208 fixed by the frame fixing unit 10 is to be divided. The upper holding unit 50 is arranged on a moving base 5. The moving base 5 is moved in the Z-axis direction by a lift unit 36 arranged on the moving table 4.

The moving base 5 is formed in the shape of a flat plate, both surfaces of which are parallel to the Z-axis direction, and is disposed over the moving table 4 with an interval in the X-axis direction therebetween. On the moving base 5, a horizontal member 6 is fixed with both upper and lower surfaces thereof lying parallel to the horizontal direction.

The lift unit 36 includes a known ball screw, a known motor 37, and known guide rails 38. The ball screw is disposed on the moving table 4, and is arranged rotatably about an axis of rotation. The motor 37 rotates the ball screw about the axis of rotation such that the moving base 5 is moved up or down in the Z-axis direction. The guide rails 38 support the moving base 5 movably up and down in the Z-axis direction.

As depicted in FIG. 7, the upper holding unit 50 includes a cylinder unit 51, an upper holding member 52, and a slide unit 53. The cylinder unit 51 includes a cylinder 54 fixed on the horizontal member 6, and a rod 55 disposed parallel to the Z-axis direction. The rod 55 is extendable and contractible relative to the cylinder 54, and when extended from the cylinder 54, its lower end is moved down.

The upper holding member 52 is formed in the shape of a rectangular plate, which is constant in thickness, is linear in the Y-axis direction, and has opposite surfaces extending parallel to the Z-axis direction. The upper holding member 52 has a length in the Y-axis direction equivalent to the length of the longest division line 203 of the wafer 200. With the rod 55 of the cylinder unit 51 fixed at the lower end thereof to an upper end of the upper holding member 52, the upper holding member 52 is disposed over the moving base 5 with an interval in the X-axis direction therebetween. The upper holding member 52 opposes, in the Z-axis direction, the rectangular holding member 44 directed upwardly from the rotor 43.

The slide unit 53 supports the upper holding member 52 slidably in the Z-axis direction relative to the moving base 5. The slide unit 53 includes linear guide rails 56 and sliders 57. The guide rails 56 are fixed on one of the moving base 5 and the upper holding member 52, specifically the moving base 5, and are parallel to the Z-axis direction. The sliders 57 are fixed on the other one of the moving base 5 and the upper holding member 52, specifically the upper holding member 52, and are supported slidably in a length direction of the guide rails 56, in other words, in the Z-axis direction on the guide rails 56.

When the upper holding member 52 is moved up by the lift unit 36 with the rod 55 extended, its lower end is located above the wafer 200 placed in the opening 209 of the annular frame 208 fixed by the frame fixing unit 10. When the upper holding member 52 is moved down by the lift unit 36 with the rod 55 extended, on the other hand, its lower end holds, between itself and the rectangular holding member 44 directed upward in the Z-axis direction from the rotor 43, the devices 204 pressed by the upwardly directed rectangular holding member 44 and located in the region adjacent in a −X direction to the division line 203 along which the wafer 200 is to be divided.

The pressing member 60 serves to press the devices 204 in the region adjacent in the −X direction to the division line 203, along which the wafer 200 is to be divided, on the opposite side in the X-axis direction to the holding members 44 and 52 of the holding unit 40 with the above-described division line 203 interposed therebetween, and hence to perform breaking (also called a “division”) of the wafer 200 along the above-described division line 203. As depicted in FIG. 7, the pressing member 60 is arranged on a pressing movable base 62 that is arranged on the horizontal member 6 movably in the X-axis direction by a second X-axis moving unit 61.

The pressing movable base 62 has opposite surfaces extending parallel to the Z-axis direction, is formed integrally including a thick portion 63 on a side of an upper end thereof and a thin portion 64 on a side of a lower end thereof, and is disposed over the upper holding member 52 with an interval in the X-axis direction therebetween. Surfaces of the thick portion 63 and thin portion 64 on a side away from the upper holding member 52 are flush with each other, and on a side close to the upper holding member 52, a step is formed between the thick portion 63 and the thin portion 64. In the pressing movable base 62, an opening 65 of a rectangular shape vertical plan view is also disposed extending through the thin portion 64.

The second X-axis moving unit 61 includes a known ball screw, a known motor 66, and known guide rails 67. The ball screw is arranged on the horizontal member 6, and is disposed rotatably about an axis of rotation. The motor 66 rotates the ball screw about the axis of rotation such that the pressing movable base 62 is moved in the X-axis direction. The guide rails 67 support the pressing movable base 62 movably in the Z-axis direction.

The pressing member 60 is formed in the shape of a rectangular plate, which is linear in the Y-axis direction, and has opposite surfaces extending parallel to the Z-axis direction. The pressing member 60 has a length in the Y-axis direction equivalent to the length of the longest division line 203 of the wafer 200. At a lower end portion of the pressing member 60, a tapered portion 68 is formed with a thickness progressively and gradually decreased downward. The tapered portion 68 is formed flat along the Z-axis direction at a surface on a side of the upper holding member 52, and, at a surface on a side away from the upper holding member 52, is oblique to both the horizontal direction and the Z-axis direction in a direction that the latter surface downwardly comes gradually closer toward the upper holding member 52.

The pressing member 60 is supported slidably in the Z-axis direction by a pair of slide units 69 on the pressing movable base 62. The paired slide units 69 are arranged with an interval in the Y-axis direction therebetween. Each slide unit 69 includes a linear guide rail 691 and a slider 692. The guide rail 691 is fixed on one of the pressing movable base 62 and the pressing member 60, specifically the pressing movable base 62, and is parallel to the Z-axis direction. The slider 692 is fixed on the other one of the pressing movable base 62 and the pressing member 60, specifically the pressing member 60, and is supported slidably in a length direction of the guide rail 691, in other words, in the Z-axis direction on the guide rail 691.

When the pressing member 60 is moved up by the lift unit 36 via the horizontal member 6, its lower end is located above the wafer 200 placed in the opening 209 of the annular frame 208 fixed by the frame fixing unit 10. When the pressing member 60 is moved down by the lift unit 36 via the horizontal member 6, on the other hand, its lower end downwardly presses the devices 204 of the wafer 200, the devices 204 being located on the opposite side in the X-axis direction to the holding members 44 and 52 with the division line 203, along which the wafer 200 is to be divided, extending in the Y-axis direction, and being interposed between the pressing member 60 and the holding members 44 and 52. The pressing member 60 downwardly presses the device 204 of the wafer 200 at a position where the distance in the −X direction from the upper holding member 52 is approximately 75% to 85% of the width of the chips 210. It is to be noted that, in the present invention, the pressing member 60 needs to downwardly press the device 204 of the wafer 200 at a position where the distance in the −X direction from the upper holding member 52 is approximately 65% to 95% of the width of the chips 210.

If the position where the pressing member 60 presses the devices 204 of the wafer 200 is at an excessively small distance in the −X direction from the upper holding member 52, the wafer 200 is difficult to be divided. If this distance is excessively large, on the other hand, the wafer 200 is not divided because the pressing member 60 slips away toward the division lines 203 along which the wafer 200 has already been divided. It is therefore desired that the pressing member 60 downwardly press the devices 204 of the wafer 200 at a position where the distance in the −X direction from the upper holding member 52 is approximately 65% to 95% of the width of the chips 210, desirably approximately 75% to 85% of the width of the chips 210. When the pressing member 60 is moved down by the lift unit 36 via the horizontal member 6, the pressing member 60 downwardly presses the devices 204 of the wafer 200, the devices 204 being located on the opposite side in the X-axis direction to the holding members 44 and 52 with the division line 203, along which the wafer 200 is to be divided, extending in the Y-axis direction, and being interposed between the pressing member 60 and the holding members 44 and 52, and divides the wafer 200 along the division line 203 along which the wafer 200 is to be divided.

The pressing member 60 is fixed on the pressing movable base 62 via a load measuring unit 70 depicted in FIG. 8. The load measuring unit 70 is arranged between the paired slide units 69. As depicted in FIGS. 8 and 9, the load measuring unit 70 includes a load meter 71 that measures the value of a load (hereinafter referred to as a “load value”) by which the pressing member 60 presses the above-described devices 204 of the wafer 200, a holding member 72, a spring 75, and a support portion 74 (depicted in only FIG. 9).

The load meter 71 serves to measure a load value in the Z-axis direction, by which the pressing member 60 presses the above-described devices 204 of the wafer 200. In this embodiment, the load meter 71 is, but not limited to, a known load cell. The load meter 71 outputs a load value as a measurement result to the controller 100. The load meter 71 is arranged in the opening 65 of the pressing movable base 62.

The holding member 72 is fixed at one end portion thereof to the pressing member 60, extends from the pressing member 60 toward the pressing movable base 62, and is arranged at the other end portion thereof in the opening 65 of the pressing movable base 62. The holding member 72 supports, at the other end portion thereof, a lower end of the load meter 71.

The support member 73 is arranged in the opening 65 of the pressing movable base 62, is fixed at an upper end thereof to an upper-side inner surface of the opening 65, and at a lower end thereof supports an upper end of the load meter 71. The support portion 74 is arranged in the opening 65 of the pressing movable base 62, is fixed at a lower end thereof to a lower-side inner surface of the opening 65, and at an upper end thereof supports a lower end portion of the holding member 72.

The spring 75 is arranged between the lower-side inner surface of the opening 65 and the other end portion of the holding member 72, and upwardly biases the pressing member 60 relative to the pressing movable base 62 via the other end portion of the holding member 72. The spring 75 upwardly biases the holding member 72 and the pressing member 60 by a force corresponding to the total mass of the pressing member 60, the holding member 72, and the load meter 71. Owing to the biasing by the above-mentioned force with the spring 75, the total mass of the pressing member 60, the holding member 72, and the load meter 71 is cancelled out, so that the load meter 71 can measure load values smaller than the total mass of the pressing member 60, the holding member 72, and the load meter 71. As described above, the breaking machine 1 includes the load meter 71 that measures the load value by which the pressing member 60 presses the above-described devices 204 of the wafer 200.

The controller 100 serves to make the breaking machine 1 perform a dividing operation to divide the wafer 200 along the individual division lines 203 by controlling the above-mentioned individual elements of the breaking machine 1 separately or in combination. The controller 100 is a computer, which includes a processing section having a microprocessor such as a central processing unit (CPU), a storage device having a memory such as a read-only memory (ROM) or a random-access memory (RAN), and an input/output interface device. The processing section of the controller 100 performs computation processing according to a computer program stored in the storage device, and outputs control signals to the above-mentioned individual elements of the breaking machine 1 via the input/out interface device to control the breaking machine 1. On the basis of each load value measured by the load meter 71, the controller 100 also determines the results of division of the wafer 200 along the corresponding division line 203, and then stores the results of the division and the corresponding division line 203 as a pair.

The display unit 110 includes a display screen 111 connected to the controller 100 to display a variety of information. Stacked on the display screen 111 of the display unit 110, a touch screen (not depicted) is also arranged as an input unit. The input unit is used when an operator inputs information or the like to the controller 100 of the breaking machine 1. The input unit is connected to the controller 100, and outputs the inputted information or the like toward the controller 100.

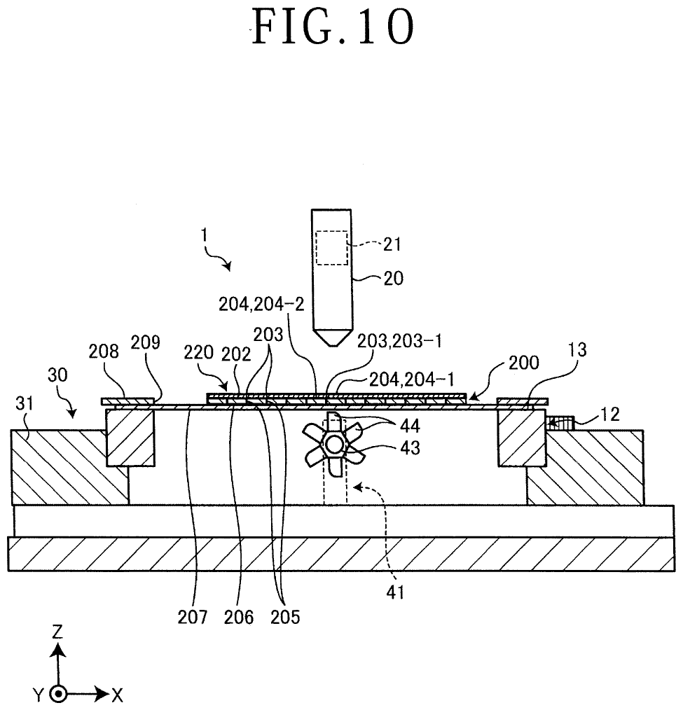

A description will next be made of the alignment step 1002. FIG. 10 is a side view schematically depicting, partly in cross-section, the alignment step of the breaking method depicted in FIG. 3. After performing the protective sheet arrangement step 1001, the alignment step captures an image of the side of the front surface 202 of the wafer 200 from the side of the protective sheet 220, and conducts position matching between the division line 203, along which the wafer 200 is to be divided, and the pressing member 60.

In the alignment step 1002, the operator or the like first operates the input unit to input dividing conditions, and the controller 100 receives and registers the dividing conditions. In the alignment step 1002, when the controller 100 receives an instruction from the operator or the like to initiate a dividing operation, the breaking machine 1 initiates the dividing operation, in other words, the alignment step 1002 in this embodiment.

In the alignment step 1002, the controller 100 controls the Z-axis moving unit 34 to make the lower holding unit 41 move down, controls the cylinder unit 51 of the upper holding unit 50 to make the rod 55 extend, and controls the lift unit 36 to make the upper holding unit 50 and the pressing member 60 move up. In the alignment step 1002, the controller 100 also controls the second X-axis moving unit 61 to adjust the position in the X-axis direction of the pressing member 60 such that the distance in the X-axis direction between the lower end of the upper holding member 52 and the lower end of the pressing member 60 falls to 75% to 85% of the width of the chips 210 as included in the dividing conditions. It is to be noted that, in the present invention, the position in the X-axis direction of the pressing member 60 needs to be adjusted so as to make the distance in the X-axis direction between the lower end of the upper holding member 52 and the lower end of the pressing member 60 fall to 65% to 95% of the width of the chips 210.

In the alignment step 1002, the controller 100 also controls the X-axis moving unit 30 to make the frame fixing unit 10 retreat from between the holding units 41 and 50. The annular frame 208 with the wafer 200 placed in the opening 209 is placed on the holding surface 13 of the frame fixing unit 10. The controller 100 then operates the suction source to draw and fix the annular frame 208 to the holding surface 13 of the frame fixing unit 10.

In the alignment step 1002, the controller 100 controls the X-axis moving unit 30 and the Y-axis moving unit 32 on the basis of a dividing order included in the dividing conditions. As depicted in FIG. 10, the detection unit 20 is positioned above the division line 203 (hereinafter denoted by “203-1”) along which the wafer 200 is to be divided, and an image of surroundings of the division line 203-1, including the division line 203-1 along the wafer 200 is to be divided, is captured by the image capture camera 21 of the detection unit 20. The controller 100 detects the division line 203-1 on the basis of the image acquired by the image capture camera 21 of the detection unit 20.

In the alignment step 1002, the controller 100 controls the undepicted rotating mechanism to direct the rectangular holding member 44, the length of which corresponds to that of the division line 203-1, upward from the rotor 43, and then controls the undepicted rotary drive mechanism to position the division line 203-1 parallel to the Y-axis direction. In the dividing step 1003, the controller 100 controls the X-axis moving unit 30 to conduct position matching between the division line 203-1 and the pressing member 60 by positioning the lower end of the upper holding member 52 above the devices 204 (equivalent to a region, and hereinafter denoted by “204-1” as indicated in FIG. 10) adjacent, on a far side in the X-axis direction (the +X direction) in FIG. 10, positioning the upper end of the upwardly directed rectangular holding member 44 below the devices 204-1 adjacent, on the far side in the X-axis direction (the +X direction) in FIG. 10, and also positioning the lower end of the pressing member 60 above the devices 204 (equivalent to another region, and hereinafter denoted by “204-2” as indicated in FIG. 10) adjacent, on a near side in the X-axis direction (the −X direction) in FIG. 10.

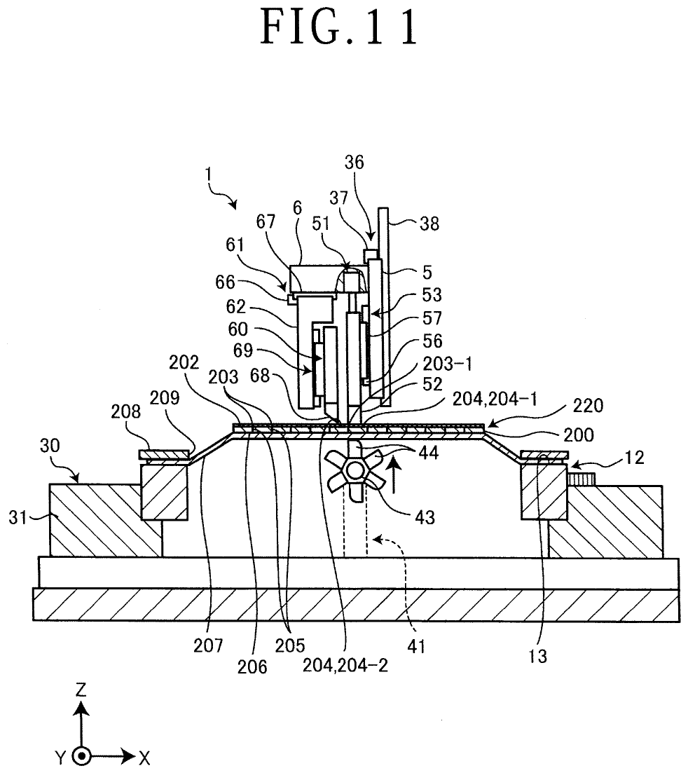

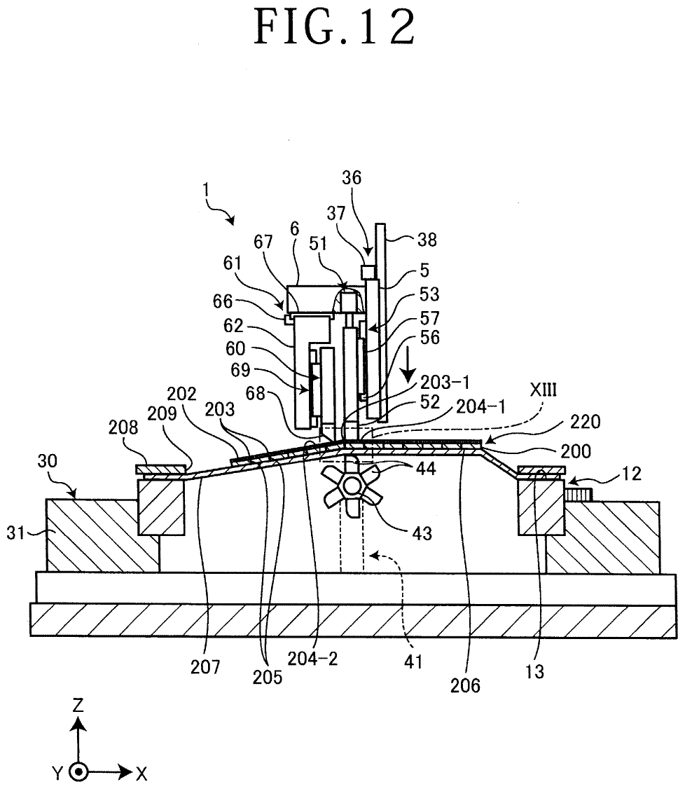

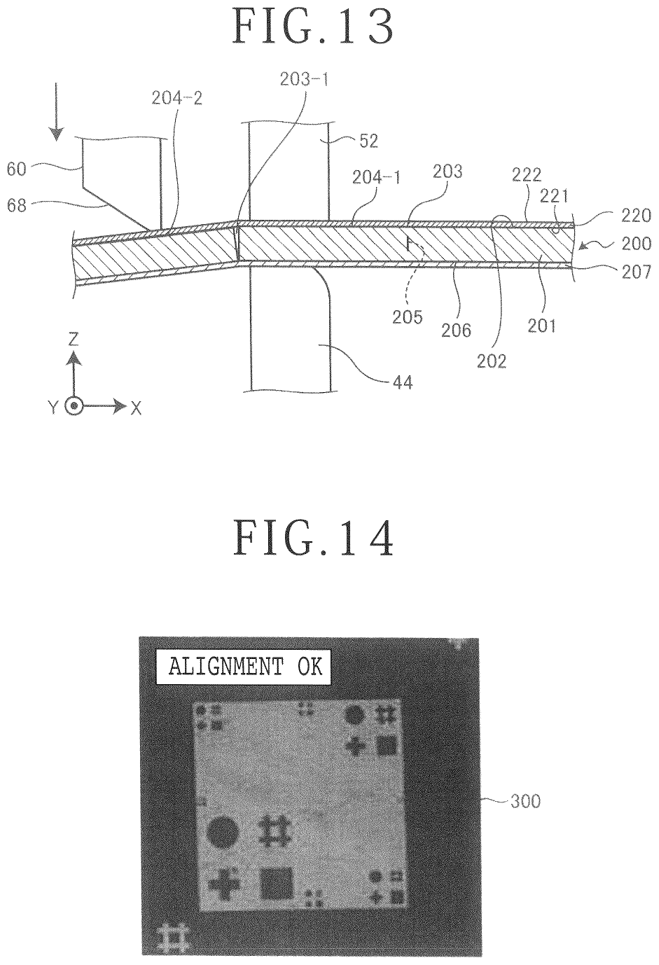

FIG. 11 is a side view schematically depicting, partly in cross-section, the dividing step 1003 of the breaking method depicted in FIG. 3, in which the devices 204-1 adjacent in the +X direction to the division line 203-1, along which the wafer 200 is to be divided, is held between the holding members 44 and 52. FIG. 12 is a side view schematically depicting, partly in cross-section, the dividing step 1003 of the breaking method depicted in FIG. 3, in which the wafer 200 has been divided along the division line 203-1. FIG. 13 is a side view schematically depicting, on an enlarged scale and partly in cross-section, a part XIII in FIG. 12.

The dividing step 1003, after performing the alignment step 1002, divides the wafer 200 along the division line 203-1 by pressing the pressing member 60 against the devices 204-2 along the division line 203-1. Described specifically, the devices 204-1 in the region adjacent in the +X direction to the division line 203-1 are held by the paired holding members 44 and 52 from above and below the wafer 200, and at the same time, the devices 204-2 in the other region adjacent to the division line 203-1 on the opposite side to the paired holding members 44 and 52 with the division line 203-1 interposed between the other region and the paired holding members 44 and 52 are pressed from the side of the protective sheet 220 by the pressing member 60, whereby the wafer 200 is divided along the division line 203-1.

In the dividing step 1003, the controller 100 controls the Z-axis moving unit 34 to move up the rotor 43 such that the devices 204-2 in the other region adjacent in the +X direction to the division line 203-1 are upwardly pressed by the upwardly directed rectangular holding member 44 via the tape 207. As a consequence, the wafer 200 is moved up, and the devices 204-1 are brought into contact with the lower end of the upper holding member 52 via the protective sheet 220. In this manner, as depicted in FIG. 11, the devices 204-1 in the region adjacent in the +X direction to the division line 203-1 are held between the holding members 44 and 52 via the protective sheet 220 and the tape 207. At this time, the lower end of the pressing member 60 is located above the front surface 202 of the wafer 200.

In the dividing step 1003, the controller 100 controls the lift unit 36 on the basis of the dividing conditions to move down the moving base 5 of the upper holding unit 50 and the pressing member 60 via the horizontal member 6. As the devices 204-1 in the region adjacent in the +X direction to the division line 203-1 are held between the upper holding member 52 and the upwardly directed rectangular holding member 44 via the protective sheet 220 and the tape 207, the rod 55 of the cylinder unit 51 is then contracted without any downward movement of the upper holding member 52, so that the upper holding member 52 is moved up by the slide unit 53 relative to the moving base 5.

When the moving base 5 of the upper holding unit 50 is moved down, the pressing member 60 is also moved down via the horizontal member 6 and the pressing movable base 62, so that the lower end of the pressing member 60 is brought into contact with the devices 204-2 on the front surface 202 of the wafer 200, the devices 204-2 being in the other region adjacent to the division line 203-1 on the opposite side to the holding units 41 and 50, via the protective sheet 220, the pressing member 60 is further moved downward, and as depicted in FIGS. 12 and 13, the lower end of the pressing member 60 is positioned blow the lower end of the upper holding member 52 to divide the wafer 200 along the division line 203-1 between the holding members 44 and 52 and the pressing member 60.

In the dividing step 1003, after the moving base 5 and the pressing member 60 are moved down, the controller 100, as specified under the dividing conditions, controls the lift unit 36 to move up the moving base 5 and the pressing member 60, and also controls the Z-axis moving unit 34 to move down the rotor 43, that is, the upwardly directed rectangular holding member 44.

In the dividing step 1003, the controller 100 also determines the results of the division of the wafer 200 along the division line 203-1 on the basis of a load value measured by the load meter 71, and stores the determined results of the division and the division line 203-1 as a pair. In the dividing step 1003, the breaking machine 1 divides the wafer 200 sequentially in the +X direction along from the division line 203 on a nearest side in the X-axis direction to the division line 203 on a farthest side in the X-axis direction. When the breaking machine 1 divides the wafer 200 into the individual chips 210 along all the division lines 203, the dividing operation, that is, the dividing step 1003, is completed. Subsequently, the divided chips 210 are picked up from the tape 207.

It Is to be noted that the dividing step 1003 is performed along only the division lines 203 extending in the Y-axis direction, and is not performed along the division lines 203 extending in the X-axis direction. As the division starting points 205 are also formed along the division lines 203 in the X-axis direction as depicted in FIG. 1, the wafer 200 is also divided along the division lines 203 in the X-axis direction when the wafer 200 is divided along the division lines 203 in the Y-axis direction.

In the breaking method according to the above-described embodiment, the front surface 221 and back surface 222 of the protective sheet 220, which is arranged on the side of the front surface 202 of the wafer 200 without thermocompression bonding in the protective sheet arrangement step 1001, remain flat. In the alignment step 1002, each division line 203-1 in the Y-axis direction can therefore be detected through the protective sheet 220 to conduct position matching.

As a consequence, the breaking method according to this embodiment exhibits advantages that a division failure of the wafer 200 can be decreased and the risk of damage to the wafer 200 upon peeling of the protective sheet 220 can also be decreased.

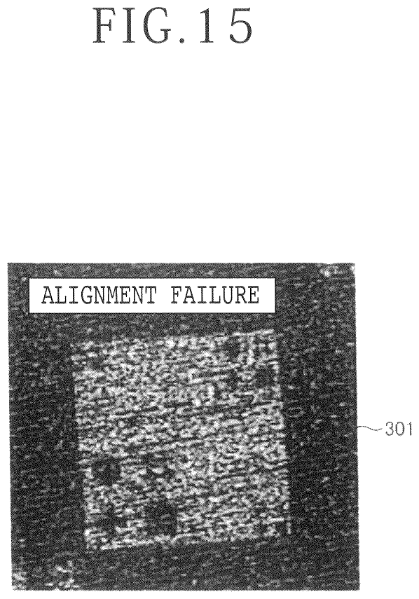

Next, the advantages of the breaking method according to this embodiment are verified. FIG. 14 is a view presenting an image 300 of the wafer 200 as acquired in the alignment step of the breaking method according to this embodiment. FIG. 15 is a view presenting an image of a wafer 200, which is of the same kind as the wafer 200 depicted in FIG. 1, as acquired using another protective sheet as a comparative example.

FIG. 14 presents the image 300 of the front surface 202 of the wafer 200 as acquired by the image capture camera 21 when a protective sheet 220 having a surface roughness (Ra) of 0.1 μm on a front surface 221 and the back surface 222 is arranged on a side of the front surface 202 of the wafer 200. FIG. 15 presents an image 301 of a front surface 202 of the wafer 200 as acquired by the image capture camera 21 when a protective sheet 220 having a surface roughness (Ra) of 1.2 μm on a front surface 221 and the back surface 222 is arranged on a side of the front surface 202 of the wafer 200.

According to the comparative example presented in FIG. 15, it is difficult to detect devices 204-1 and 204-2, in other words, a division line 203-1, from the image 301. In contrast to such a comparative example, it is possible to detect the devices 204-1 and 204-2, in other words, the division line 203-1, from the image 300 presented in FIG. 14.

According to FIGS. 14 and 15, it has hence been found that, by arranging a protective sheet 220 having a surface roughness (Ra) of 0.01 μm or greater and 0.5 μm or smaller on the side of the front surface 202 of the wafer 200 without thermocompression bonding, an alignment can be performed, a division failure of the wafer 200 can be decreased, and the risk of damage to the wafer 200 upon peeling of the protective sheet 220 can be also decreased.

The breaking method according to this embodiment also includes the protective sheet arrangement step 1001 that arranges the protective sheet 220 on the side of the front surface 202 of the wafer 200. In the dividing step 1003, the breaking method according to this embodiment therefore presses the devices 204-2 of the wafer 200 by the pressing member 60 via the protective sheet 220 maintained in close contact with the front surface 202 of the wafer 200. There is hence no problem of penetration of dividing debris between the front surface 202 of the wafer 200 and the protective sheet 220.

The breaking method according to this embodiment therefore exhibits an advantage that damage to the wafer 200 upon its division can be suppressed.

In the breaking method according to this embodiment, the protective sheet 220 is what is called a glue-free tape formed with only a base material layer of a non-self-adhesive thermoplastic resin. A resin that would otherwise make up a glue layer hence does not remain on surfaces of the devices 204 after removal of the protective sheet 220.

It is to be noted that the present invention shall not be limited to the above-described embodiment. In other words, the present invention can be practiced with various modifications within the scope not departing from the spirit of the present invention. For example, the tape 207 in the present invention may be a sheet that, similarly to the protective sheet 220, is free of any glue layer, is formed with only a base material layer of a thermoplastic resin, and exhibits an adhesive force when heated.

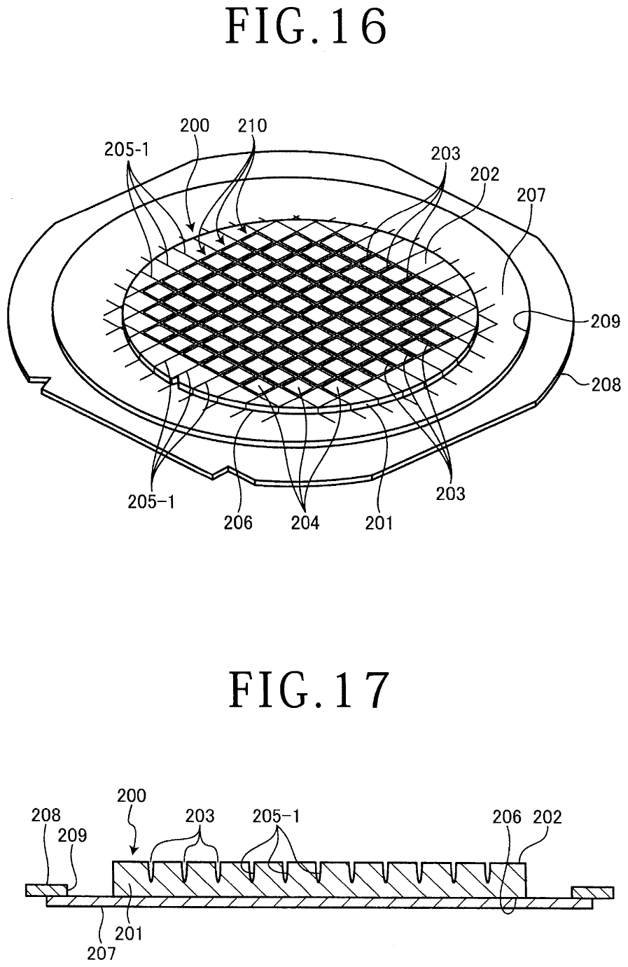

In the present invention, as depicted in FIGS. 16 and 17, processed grooves which are recessed from a front surface 202 may be formed as division starting points 205-1 along division lines 203 in another wafer 200. The processed grooves are formed by applying cutting processing to the division lines 203 or applying a laser beam of a wavelength which has absorptivity for the other wafer 200, to the division lines 203.

FIG. 16 is a perspective view schematically depicting the other wafer 200 as a modification of the wafer 200 depicted in FIG. 1. FIG. 17 is a cross-sectional view schematically depicting the other wafer 200 depicted in FIG. 16. In FIGS. 16 and 17, portions identical to those of the wafer 200 in the embodiment are identified by the same reference numerals, and their description is omitted.

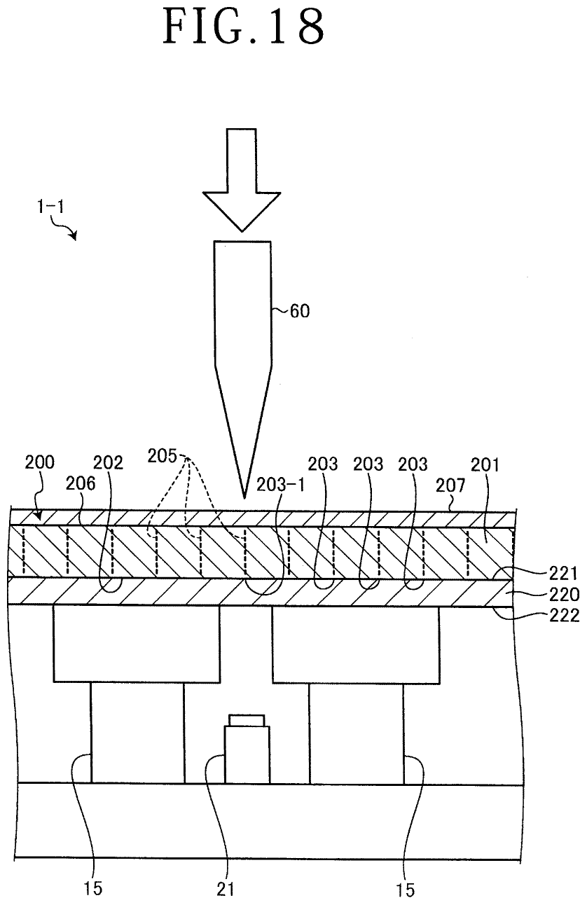

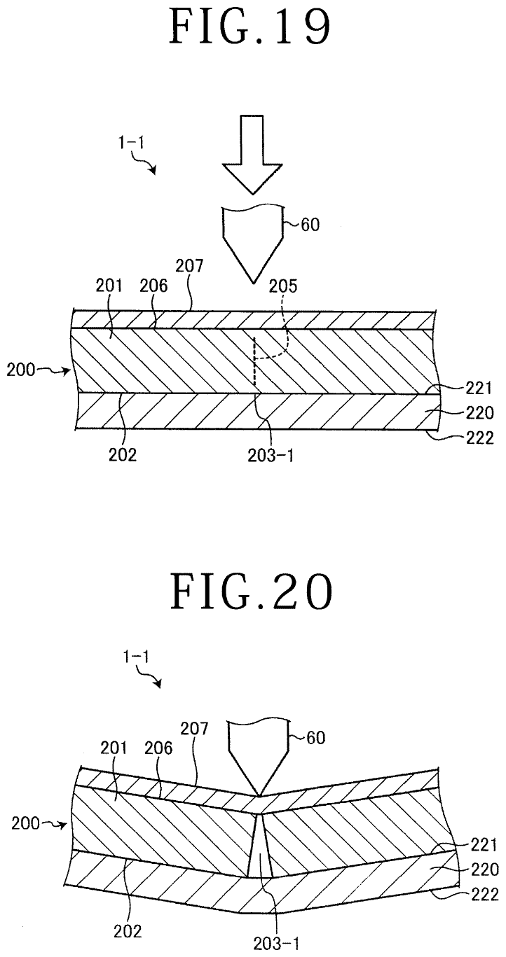

In the present invention, the alignment step 1002 may be modified, for example, as depicted in FIG. 18. Described specifically, a front surface 202 of a wafer 200 may be placed on an annular support base 15 of a breaking machine 1-1 with a protective sheet 220 interposed therebetween, and an image of the front surface 202 of the wafer 200 may then be captured through the protective sheet 220 by the image capture camera 21 arranged in an inner space of the support base 15. In this case, as depicted in FIGS. 19 and 20, the wafer 200 is divided by pressing a division line 203-1 on a side of a back surface 206 via a tape 207.

FIG. 18 is a side view schematically depicting, partly in cross-section, the modification of the alignment step depicted in FIG. 10. FIG. 19 is a side view schematically depicting, partly in cross-section, a modification of the dividing step depicted in FIG. 11. FIG. 20 is a side view schematically depicting, partly in cross-section, a modification of the dividing step depicted in FIG. 12. In FIGS. 18, 19, and 20, portions identical to those of the wafer 200, tape 207, protective sheet 220, and pressing member 60 in the embodiment are identified by the same reference numerals, and their description is omitted.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A breaking method for dividing, along a division line, a wafer having division starting points formed along the division line, comprising:
a protective sheet arrangement step of arranging, on a side of a front surface of the wafer, a protective sheet that has a front surface and back surface formed flat and is free of any glue layer;
an alignment step of, after performing the protective sheet arrangement step, capturing an image of the front surface of the wafer from a side of the protective sheet and conducting position matching between the division line and a pressing member; and
a dividing step of, after performing the alignment step, dividing the wafer along the division line by pressing the pressing member against the wafer along the division line.

2. The breaking method according to claim 1, wherein the protective sheet contains an antistatic agent.

3. The breaking method according to claim 1, wherein, in the dividing step, the wafer is held from above and below thereof by a pair of holding members in a region adjacent to the division line, and at the same time, the wafer is pressed from the side of the protective sheet by the pressing member in another region adjacent to the division line on an opposite side to the paired holding members with the division line interposed between the other region and the paired holding members, whereby the wafer is divided along the division line.
